(19) United States
(12) Patent Application Publication
(10) Pub. No.: US 2021/0013175 A1
(43) Pub. Date: Jan. 14, 2021

(54) METHOD OF ASSEMBLING A SEMICONDUCTOR POWER MODULE COMPONENT AND A SEMICONDUCTOR POWER MODULE WITH SUCH A MODULE COMPONENT AND MANUFACTURING SYSTEM THEREFOR

(71) Applicant: Danfoss Silicon Power GmbH, Flensburg (DE)

(72) Inventors: Frank Osterwald, Nordborg (DK); Holger Ulrich, Nordborg (DK)

(21) Appl. No.: 17/041,689

(22) PCT Filed: Mar. 18, 2019
(86) PCT No.: PCT/EP2019/056730

§ 371 Date: Sep. 25, 2020

(30) Foreign Application Priority Data
Mar. 29, 2018 (DE) 10 2018 204 887.8

(51) Int. Cl. H01L 23/00; H05K 13/04; H01L 21/50; H01L 21/48

(52) U.S. Cl. CPC H01L 24/83; H05K 13/0465; H01L 21/50; H01L 2021/60097; H01L 24/75; H01L 24/29; H01L 21/4853

(57) ABSTRACT

A method of assembling a semiconductor power module component 30 and a manufacturing system comprising such a semiconductor power module component and a pressing apparatus 20 for manufacturing a semiconductor power module component are described. The semiconductor power module component 30 comprises at least a first element 1, a second element 2 and a third element 3 arranged in a stack 10. The first element 1 and the second element 2 are joined by sintering in a sintering area 4 and the second element 2 and the third element 3 are joined by soldering in a soldering area 6. The sintering and the soldering are simultaneously executed, wherein the soldering area 6 is heated to a temperature of soldering and the sintering area 4 is heated to a temperature of sintering, the temperature of soldering and the temperature of sintering being harmonized to each other. Pressure is being applied to the stack 10, comprising the at least one soldering area 6 and the at least one sintering area 4 with stabilizing means 7 being arranged in the soldering area 6.

### CROSS-REFERENCE TO RELATED APPLICATIONS

This application is a National Stage application of International Patent Application No. PCT/EP2019/056730, filed on Mar. 18, 2019, which claims priority to German Patent Application No. 102018204887.8 filed on Mar. 29, 2018, each of which is hereby incorporated by reference in its entirety.

### TECHNICAL FIELD

The invention relates to a method of assembling a semiconductor power module component and a semiconductor power module with such a module component having component parts which are sintered together and having component parts which are soldered together, as well as a manufacturing system comprising a semiconductor power module component to be assembled and a pressing apparatus pressing the stack for a semiconductor power module component to such a module component.

### BACKGROUND

Semiconductor power modules comprise some form of a semiconductor switch such as an IGBT, MOSFET or other control semiconductor switch suitable for switching of electrical currents.

These switches are mounted on a substrate and are connected to electrical conductors allowing electrical currents to flow in and out of the device, connections being provided to control the operation of the semiconductor switch. The mounting means of the semiconductor component parts onto the substrate has to be of low electrical conductivity and of high reliability. During operation the semiconductor component is liable to reach high temperatures and is also liable to cycle in temperatures so that it is also important that the mounting means of the semiconductor component parts onto the substrate is of high thermal conductivity and of high reliability under occasionally high temperature conditions and temperature cycling. Because of these temperature conditions, the substrate is normally further connected to some form of base plate or heat sink in order for the heat generated by the semiconductor component part to be conducted out of module. Furthermore, the connection means between the substrate and the base plate also needs to have high thermal conductivity and high reliability.

For connecting the semiconductor component parts to the substrates and the substrates to the base plate various means are available. Connection means for these connections are sintering and/or soldering.

Semiconductor power module components are typically assembled from various elements to form a “thermal stack”, an assembled set of components through which heat is conducted from the heat generating component part which normally is the semiconductor chip itself, to an external heat sink. This power semiconductor chip represents the core of the entire structure. The chip is usually mounted on a substrate. For example, this might be a substrate comprising an insulating sheet with conducting layers on each side, such as a direct copper bond (DCB) substrate, the insulating sheet being formed of a ceramic and the conducting layers being formed of metal, in this case copper. The substrate itself forms part of the electric circuit and is configured in a manner corresponding to the function with, for example, the upper conducting layer formed as conducting circuit elements, forming electrical contact between the electronic component parts mounted thereon. For providing a structure which conducts heat very well and at the same time introduces high mechanical stability into the structure, the substrate maybe joined to a base plate typically consisting of copper. Optionally, aluminium or other suitable metal, or a ceramic, may be used. Optionally, this base plate can be structured on the side opposite to the side on which the substrate is mounted for an efficient cooling action using direct liquid cooling, or it can optionally contain cooling channels or the like which the coolant may pass through in order to extract heat from the module component arranged as a stack of various component parts. The thermal stack including the semiconductor chip may additionally comprise a thermal buffer on the chip which represents an additional high-heat-capacity part such as a metal layer on the side of the chip remote from the substrate. It is also possible that wire bods, bands, clips, busbars or the like can be applied as contact elements. Using a second substrate on the upper side of the semiconductor chip might as well be appropriate.

For the joins between the chip, the substrate and the base plate a soldering process using soft solder is usually used. This can be built up by a succession of individual process steps for the various soldering joining planes in the thermal stack, starting with the joining requiring the highest temperature, which is then stable under the lower joining temperature required for the subsequent process steps, and then proceeding with the next highest temperature join. Depending on the structure of the stack, alternatively, a single process step of simultaneously solder joining all joining planes can be utilized.

The latter kind of process saves manufacturing time.

For carrying out the above soldering process, heat will have to be supplied to the structure, which, optionally, can be done under a controlled process atmosphere. This can be enabled by thermal contact with hot plates, by inductive heat transfer or in any other known way. Sometimes even for soldering a certain pressure profile can also be applied in addition to applying temperature profiles. A combination of different temperature/pressure profiles in a process chamber, for example, for a vacuum soldering, can be employed in order for hole-free, large-area soldered joins to be obtained.

It is also known to use sintered joins, usually silver-sintering pastes being employed, instead of soldered joins. Sintered joins require pressure to be applied in order to carry out the sintering process. The process pressure necessary for sintering can be applied in the form of a uniaxial pressure by means of a pressure apparatus of the kind of a solid die or else by a quasi-hydrostatic pressure device applying the pressure to the component parts to be sintered by the use of a soft cushion arranged in a closed press tool chamber. By applying such a pressure apparatus the chips are joined by sintering, using sintering pastes, to a substrate by applying pressure and heat.

It is also known in prior art that during sintering a semiconductor chip onto a substrate a thermal buffer is, simultaneously with the pressure sintering of the chip and of the substrate, sintered onto the surface of the chip opposite to that surface connected to the substrate which is a thermal buffer, for example one comprising copper. Such a thermal buffer may comprise a copper body joined to the chip surface and acting as a thermal reservoir to reduce the temperature extremes of temperature cycling and/or acting as a protective layer to the semiconductor chip when connectors such as wire bonds are being connected to the chip. It is known in the prior art to carry out several sinter joins in one single process step.

Considering the above, it is conceivable to carry out joining of the substrate with the base plate by simultaneously sintering the chip and the substrate join and, if required, also simultaneously sintering the chip and the thermal buffer join. However, it is known in the prior art that this process involves quite a lot of difficulties occurring in such a wide-ranging combined process which have not been able to be overcome yet. The reason is that it has not been possible to match all the process parameters required in order that all the joins can be sintered together simultaneously. The process parameters which are the most difficult to match are the temperatures and pressures and/or the variations of temperature/pressure with time.

In addition thereto, the design of sintering press tools represents a difficulty, because the hard sintered connection required between a DCB and a base plate imposes a challenge to the thermo-mechanical integrity of the connection, e.g. to deal with the considerable warping of the structure that occurs when it is cooled down from the process temperature. It is also known and common practice for a DCB substrate to be soldered to a base plate. A recurring disadvantage is involved in the transfer of process heat to the component parts during soldering because of poor heat transfer from a hot plate to the component parts resting thereon. This is particularly true for the case when the component parts are clamped but do not have sufficient contact surface. To prevent uncertain process results from occurring it has been tried to press component parts, such as the thermal stack, firmly onto the hotplate during soldering which, however, would lead to the expulsion of the solder material once melted and would lead to a solder-poor and therefore low-quality join.

Furthermore, it has to be considered that solder joins of chips comparatively easily reach their limits of long-stressability because the strength of solder material is dramatically reduced at relatively high operating temperatures. The higher the power load for the semiconductor power module component, the higher will be the temperatures this module component is exposed to. The closer the operating temperature is to the melting point, the less strength the material can be expected to have. This is described by the homologous temperature T_{H} which is defined as ratio of the operating temperature (in Kelvin) to the melting point of the solder material (also in Kelvin): As a formula

T_{H}=T/Tₘₚ.

In order to be able to guarantee long-term reliability and high temperature durability for the module components during normal operation, it has been tried to replace soldering technology by sintering technology for power electronic application at relative high temperatures. It has to be borne in mind that the semiconductor junction temperature of which are even today up to 175° C. or even up to 200° C. are, for this reason, preferably sintered.

Just because the operating temperatures of the large area joins between a substrate and a base plate are significantly below the ones of the close-to-chip joining planes, these large-area joins are usually still being soldered because at lower temperatures the strength of the solder is generally sufficiently high. Mechanical elasticity of the solder material which is sometimes able to equalize thermo-mechanical stresses arising between substrate and a base plate is also particularly welcome for large area joins. A sinter join is not able to ensure this to the same extent.

A decisive disadvantage of the prior art when combing sinter joins in the close-to-chip joining planes and the solder joins in the large-area joining planes, (that means joining planes between substrate and base plate), is the fact that the two different process steps have to be carried out in succession, increasing the time of manufacture of such semiconductor power module components. These process steps are:

Firstly, the close-to-chip joins have to be produced by sintering under pressure with pressures typically been as high as 10 to 30 MPa and elevated temperatures typically as high as 250° C. to 280° C.;

Secondly, the substrate provided with sintered component parts is subsequently joined to the base plate in a soldering process at elevated temperatures typically as high as 250° C. to 280° C. This soldering process is carried out without pressure application because otherwise the liquid solder material at the temperatures mentioned could be pressed out of the soldering layer.

In EP 2 560 468 A1 a method of connecting elements of a plurality of elements to one another is described. The component to be manufactured comprises sintering and soldering joins. Those component parts which are to be sintered together will be applied with an appropriate pressure for the sintering process to take place, though only those component parts. Those component parts which are to be soldered together will not be applied with pressure. Sintering and soldering processes are being carried out partially simultaneously with regard to heating both the sintering areas and the soldering areas. That means, as far as sintering and soldering is concerned, simultaneous heating, or partial simultaneous heating, takes place both for the component parts to be sintered and the component parts to be soldered. This could lead to a reduction of manufacturing time. However, on the one hand these two different processes take place at least partially at different times, and on the other hand a tool applied to impose pressure to those component parts which are to be sintered together has to be as small as not to cover the entire size of the module component. Furthermore, it is suggested that the applying of pressure may be executed subsequently to the heating of the elements to be sintered and to be soldered.

### SUMMARY

The object of the present invention is to provide a method and a manufacturing system for semiconductor power module components by means of which soldering and sintering can be efficiently carried out with high strength and reliability of the joins during operation including at high and under cycling temperatures.

According to the invention a method for manufacturing, i.e. assembling, a semiconductor power module component is described, which provides for sintered and soldered joins being created simultaneously in one process step with the application of heat and pressure both for the sintering and soldering joins.

According to a first aspect of the invention a semiconductor power module component is assembled which comprises at least a first element, a second element and a third element representing the component parts and arranged in a stack wherein the first element and the second element are joined by sintering in a sintering area and the second and the third element are joined by soldering in a soldering area. According to the invention sintering and soldering are simultaneously executed wherein the soldering area is heated to a temperature of soldering and the sintering area is heated to a temperature of sintering. The temperature of soldering and the temperature of sintering are harmonized to each other. Harmonizing the temperature of soldering and the temperature of sintering means, that both for sintering and soldering more or less the same temperatures are applied. Once the temperature is as high as to start sintering, pressure will be applied to the stack comprising at least one soldering area and the at least one sintering area. When the soldering area with the solder paste has reached more or less the temperature of sintering the solder will usually be liquefied. When pressure is being applied to the stack, this would normally result to squeezing out the liquid solder out of the soldering area. In order for the liquid solder not to be pressed out of the solder layer, stabilizing means are provided within the soldering layer which are able to take up pressure without being compressed significantly. The stabilizing means take up the pressure and provide the space so that sufficient solder material will remain in the soldering area despite the pressure applied to the module to carry out the sintering process. Once the sintering process has been finished, the temperature of the module it was exposed to during sintering and soldering can be reduced so that after the temperature having reached again ambient temperature soldering process and sintering process will be finished.

Preferably the pressure is applied to the complete area of the module component covering or overlapping the entire module component with all component parts to be assembled. However, it is also possible, to apply pressure only to those stacks or to that stack of the module component where sintering and soldering will have to be carried out completely simultaneously.

According to a further embodiment the stabilizing means are bumps which are arranged on a surface of the second element facing the third element or on surface of the third element and facing the second element. These bumps are preferably parts of the respective elements, i.e. component parts, and provide sufficient space between the two elements to be soldered together so that at a state when the solder paste has been liquidized even under the application of pressure the liquidized solder material will not be squeezed out of the solder area between the components to be soldered together.

Preferably the stabilizing means are of a material that remains solid during soldering even at the temperature of soldering. This is necessary to take up the pressure necessary for carrying out the sintering process.

According to further embodiments the stabilizing means are solid spacer means which are placed between the second element and the third element, particularly the spacer means are incorporated with a soldering material to form a solder preform. The solder preform again is still solid at the pressure and temperature of the sintering process.

According to a further embodiment the solder preform comprises substantially spherical bodies made of metal, in particular made of copper, the spherical bodies preferably are glass or ceramics or even comprise a wire mesh, in particular made of metal, in particular copper. The wire mesh which also remains solid during sintering at the temperature of sintering has the advantage of uniformly taking up the pressure within the soldering layer when the pressure is applied to the components to initiate and carry out the sintering process.

Furthermore, according a further embodiment the second element is a DCB substrate and/or the third element is a base plate.

According to a further embodiment additional component parts are sintered onto the first element and/or the second element simultaneously with the sintering and the soldering of the stack. For increasing the versatility and flexibility of the module component such additional component parts can be provided and can be—with the inventive method—sintered onto the respective element, i.e. component part.

According to a second aspect of the invention a manufacturing system is described, that comprises a semiconductor power module component having at least a first element, a second element and a third element representing component parts and being assembled as a stack, and a pressing apparatus having a heating and a pressing component. The first element and the second element of the module component as the first part of the manufacturing system are joined by soldering in a soldering area of the stack and the second element and the third element are joined by sintering in a sintering area of the stack by means of the application of the pressing apparatus to the entire stack during the entire process of sintering and soldering. Heating or supply of heat energy to this stack is realized by the heating component. The heating is taking place to a soldering temperature and to a sintering temperature wherein the heating temperature and soldering temperature are harmonized to each other. Harmonizing this temperature means that both sintering and soldering take place at the same, or similar, temperatures. Once the sintering temperature has reached, at this temperature the solder will be completely liquidized. At this point of the process, the pressing is carried out or pressure is applied by the pressing component which comprises a soft cushion-like element which is as big as to overlap or surround the component parts of the module component completely. By dimensioning the pressing apparatus or pressing component to cover the entire structure of the module component it is ensured that the entire stack is being applied with pressure both to the sintering area and the soldering area. The soft cushion-like element is housed in an internal and an external boundary element which is displaceable against each other so that once pressure is applied to the stack the cushion-like element will be compressed so that a pressure in the form of hydrodynamic pressure is applied to the entire stack high enough and gently enough not to damage the sensitive elements of the module component though to provide for sintering conditions as well.

According to a further embodiment the semiconductor power module component comprises a stabilizing means within the soldering area for taking up the pressure exerted by the pressing apparatus and thereby preventing solder material from being squeezed out of the soldering area. This stabilizing means ensures that soldering can take place even under the application of pressure required for the sintering process without imposing any harm to the quality of the soldering join because the liquid solder is kept within the solder area by the stabilizing means which acts as a spacer between the component parts to be soldered together though that there is sufficient space for the solder to remain there even when pressure is applied to the component parts.

To that extent the stabilizing means is essential for carrying out both sintering and soldering simultaneously under pressure actually required for sintering and actually not required for soldering. The stabilizing means could be a solder preform comprising a stabilizing mesh or spacers or the like for the solder join arranged in the joining plane between the substrate and the base plate. The solder preform may also comprise a mesh or some kind of a net or grating or scrim made of copper or any other suitable solid metal wire surrounded by a solder material. During the soldering process, when the stack is heated, the copper wires remain solid whilst the solder changes phase from solid to liquid and thus the liquid solder is kept within the spaces between the wires of the mesh and maintaining a gap between the surfaces being soldered together to form the solder layer whilst transmitting the force from the pressure being applied during the process simultaneously being accomplished for sintering as well.

The stabilizing means could be, so to say as an alternative to the copper mesh, a distribution of copper spheres, or spheres made of any other suitable material, which have a size to maintain a minimum spacing between the solid surfaces being joined. It is also possible for glass spheres to be applied as part of the solder preform to function in a similar manner. All these embodiments have in common that the solder surrounding the spacer material melts and firmly binds the spacer into the solidified solder matrix once the solder is cooled and chances phase from liquid to solid whilst during the liquid phase of the solder the spacer material is able to take up the pressure applied by the pressing apparatus.

These spherical particles must have a diameter in the desired solder layer thickness for solid nets. For wire meshes it is the crossing points of the crossover wires that define the solder layer thickness.

As a matter of course sinter joins are selected for the joins close to the semiconductor chip. According to the invention all joining planes are joined simultaneously in a single process step wherein pressure is applied to the complete stack and thermal energy is also introduced into the structure. It is also possible to utilize additional process atmospheres or process chambers to introduce defined pressure profiles for process optimization.

Process atmospheres may for example comprise inert gases such as nitrogen, process gases such as formic acid or a combination thereof which provides for a low-oxygen atmosphere.

The absolute process chamber pressure may vary from below 10 mbar to about 1.5 bar absolute.

A good soldering result is to be expected just because the application of pressure particularly advantageously influences the heat transfer from heating elements to the structure. As a matter of course, there is also a good sintering result likewise to be expected since temperatures and pressures in the process can, without any disadvantage for the solder joins, be adapted to the requirements for the sintered joins. The applied pressure can be opposed or taken up by the stabilizing forces of the mesh or the spacers of the solder preform when using these solder preforms so that a uniform solder gap with the sintered close-to-chip joins will simultaneously be formed. Because of the fact that pressure is applied to the entire structure, the heat transfer from a hotplate to the structure, for example a base plate with cooling structure on the underside, can be achieved. This would not be possible, or possible only in a limited way, without applying pressure. The joining materials which are most advantageous for the respective joining planes may include the following:

Sintering pastes, particularly silver sintering pastes, for the small-area joining planes close to the semiconductor chip which joining planes are, however, subjected to very large and relatively frequent temperature fluctuations, and

solder materials for the large-area joining planes which are further away from the semiconductor chip and tend to be subjected to smaller and low temperature fluctuations.

As far as a current point of view is concerned, silver- and copper-based sinter pastes would be most suitable.

In preferred embodiments tin-silver, tin-silver-copper, tin-antimony and indium-based solders are suitable for the inventive method. If for example, the melting point of the solder alloys is chosen to be in the range of 210° C. to 320° C., the process temperatures are most likely to harmonize with the sintering temperature for the sintering pastes and thus enable reliable solder joins to be achieved apart from reliable sinter joins.

The basic steps for the preferred method of assembling the semiconductor power module stack, i.e. module component, would be as follows:
a) Applying sinter paste to a substrate or a chip which could be carried out by printing or by spraying or painting;
b) picking and placing the chip onto the sinter paste on the substrate;
c) preassembling of the substrate, if required, wherein preassembling comprises adding other component parts or other connections;
d) applying the preassembled substrate to a stack of base plate and solder with included stabilizing means in the form of spacers;
e) supplying heat energy to the stack to temperature of sintering and temperature of soldering, these temperatures being harmonized to each other;
f) feeding the stack of base plate and preassembled substrate into the sintering-soldering processing press and carrying out sintering and soldering at the respective temperature according to e).

For a module requiring a thermal buffer, such a stack with a thermal buffer can be placed by applying paste to the chip or the buffer and placing this kind of stack on the chip before carrying out step a) or after step b).

### BRIEF DESCRIPTION OF THE DRAWINGS

Further details of inventive embodiments are described in the subsequent drawing wherein:

FIG. 1 illustrates the inventive method according to a first embodiment in its simplest form (FIG. 1a) to FIG. 1e));

FIG. 2 shows a similar embodiment of the invention with a DCB substrate comprising a ceramic center (FIG. 2a) to FIG. 2f));

FIG. 3 illustrates a similar process of FIGS. 1 and 2 with additionally a thermal buffer on the semiconductor chip (FIG. 3a) to FIG. 3e));

FIG. 4 shows a pressing apparatus for the soldering and sintering step (FIG. 4a) to FIG. 4b));

FIG. 5 shows a further embodiment of a fully assembled module after the soldering and sintering step;

FIG. 6 illustrates a stabilizing means with bumps at the substrate prior to (FIG. 6a)) and after soldering (FIG. 6b));

FIG. 7 represents stabilizing means in the form of separate space elements prior to (FIG. 7a)) and after soldering (FIG. 7b));

FIG. 8 shows an embodiment for a soldered preform and how it is assembled (FIG. 8a) and FIG. 8b));

FIG. 9 shows two embodiments of a semiconductor power module; and

FIG. 10 shows a flow chart reflecting the method steps for manufacturing the semiconductor power module component according to the invention.

### DETAILED DESCRIPTION

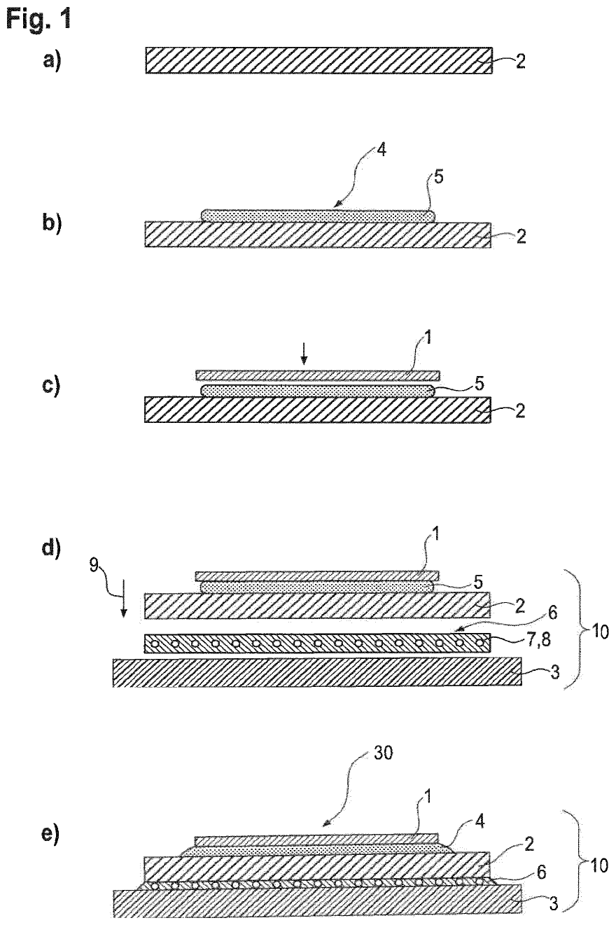

FIG. 1 illustrates the method according to the invention in its simplest form.

In FIG. 1a) a substrate 2 is represented onto which according to which FIG. 1b) sintering paste 5 is applied onto the upper surface of the substrate 2 which represents the sintering area 4.

FIG. 1c) shows the way a semiconductor chip 1 is placed on top of the sintering paste the pre-applied to the substrate 2. It would also be possible to apply the sintering paste to the semiconductor chip initially and then place the chip 1 onto the top of the substrate 2. The arrow in FIG. 1c) stands for placing the semiconductor chip 1 which represents the first element of a stack 10 onto the sintering paste 5.

FIG. 1d) shows the substrate 2 with the sintering paste on top thereon with the semiconductor chip 1 placed onto the sintering paste 5. The substrate 2 is placed onto a base plate 3 with a stabilizing means 7 in the form of a solder preform 8 between the second element 2 in the kind of the substrate and in the third element 3 in the form of a base plate. The solder preform 8 is formed from a metallic mesh within a soldering material. The solder preform 8 can be tailored to the required size of the substrate to be attached to the base plate. Once this structure (stack 10) consisting of the first element 1 to be the semiconductor chip, the sintering paste 5, the second element 2 in the form of the substrate, the stabilizing means 7 in the form of a solder preform 8 and the third element 3 in the form of the base plate is placed into a sintering/soldering press and heated whilst pressure is applied vertically through the structure (see arrow 9), sintering and soldering take place.

FIG. 1e) represents the structure after the soldering and sintering process for the joins (the sinter join and solder join) are completed. This structure can also be referred to as the soldered and sintered stack 10.

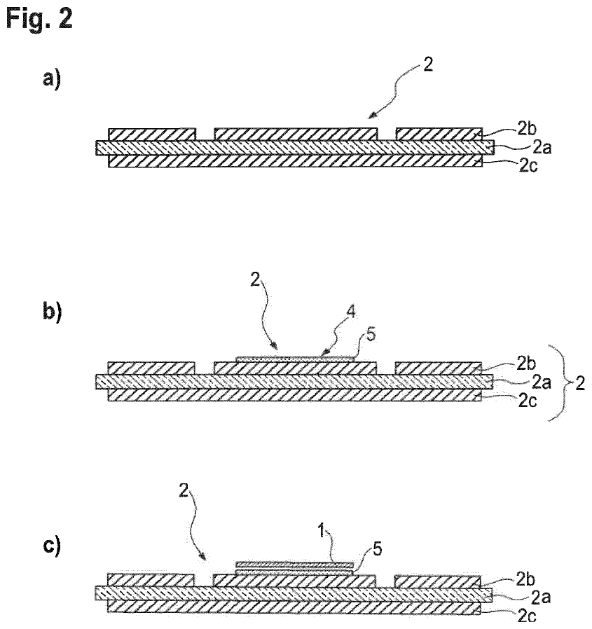

FIG. 2 shows a similar embodiment as represented in FIG. 1 with the difference that the second element 2 in form of the substrate is a DCB substrate comprising a ceramic center 2a) as an insulating layer with a top copper layer 2b) and a bottom copper layer 2c) on the upper side of the substrate and the lower side of the substrate, respectively. The top copper layer 2b) is broken up into circuit elements to form conducting tracks as required by the defined topology of the power module.

FIG. 2a) represents the substrate in the form of a ceramic centered layer with a top copper layer 2b) and a bottom copper layer 2c).

FIG. 2b) represents the partial structure 2 according to FIG. 2a) with a sintering area 4 on top of the middle part of the DCB substrate with sintering paste 5 applied on the upper side of the middle part of the DCB substrate, the complete substrate being comprised of the ceramic insulating layer 2a), the top copper layer 2b) and the bottom copper layer 2c).

FIG. 2c) corresponds to FIG. 2b) with the first element 1 in the form of a semiconductor chip just about to be placed on top of the sintering paste 5.

FIG. 2d) shows additional components 15 just about to be placed on other parts of the upper tracks of the DCB substrate with sintering paste 5 therebetween. When the sintering process takes place the semiconductor chip 1 and the additional component parts 15 are each sintered together onto the respective tracks of the top copper layer 2b) of the DCB substrate 2. These additional component parts 15 may be resistors, capacitors, inductors, diodes etc. That means electronical component parts required by the circuitry on the upper surface of the DCB substrate. It is advantageous for these additional component parts 15 to be sintered in place as well since sintering is highly reliable and can take place simultaneously with joining of the other component parts in the power module component;

FIG. 2e) is similar to the described method according to FIG. 1, however, with the DCB substrate 2 having placed thereon additional component parts 15 and meant for soldering to the base plate 3 with a solder preform 8 therebetween. This arrangement of the stack 10 is prepared for sintering and soldering to be carried out simultaneously under the pressure exerted by the pressing apparatus (not shown here).

FIG. 2f) shows the structure after temperature and pressure were applied when sintering and soldering joins are completed.

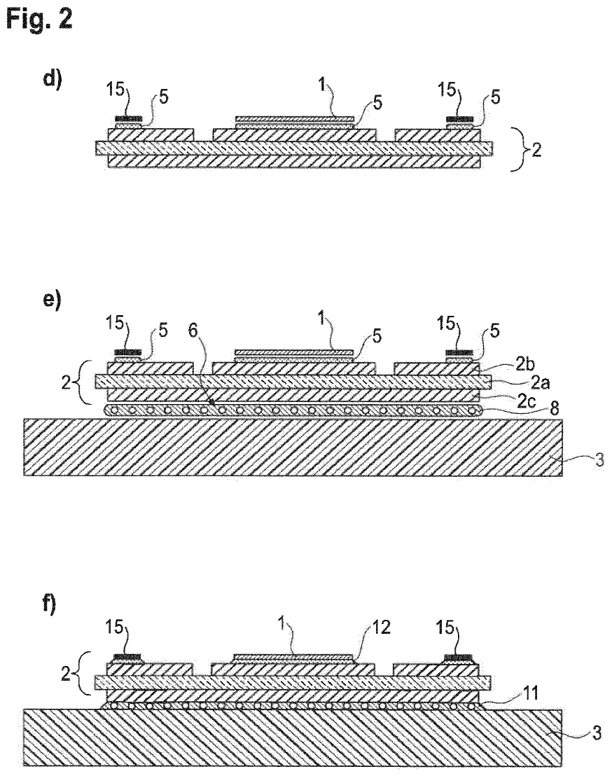

FIG. 3 represents a similar process as the one according to FIG. 2, but with a thermal buffer 14 as an additional component part just about to be placed on top of the semiconductor chip 1 with a sintering layer 5 therebetween. The sintering paste 5 for sintering the thermal buffer 14 onto the semiconductor chip 1 can be placed onto the surface of the thermal buffer 14 facing to the semiconductor chip 1 or can also be placed thereinstead onto the upper surface of the semiconductor chip 1 facing to the lower side of the thermal buffer 14. The entire stack 10 just about to be sintered and soldered by means of applying pressure 9 and heat, represented by the arrows, is represented in FIG. 3d). And finally, FIG. 3e) shows the complete structure after soldering and sintering step have taken place simultaneously.

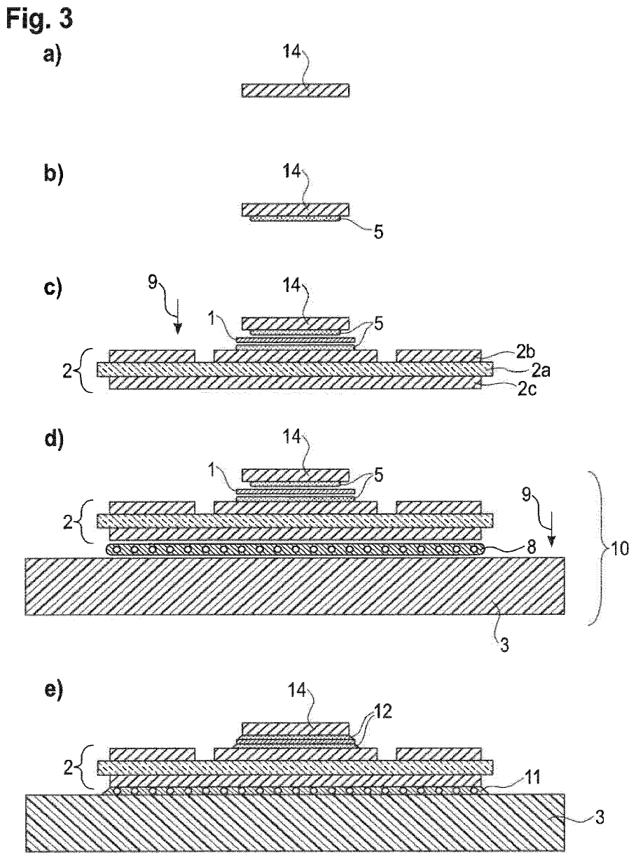

FIG. 4 shows a pressing apparatus 20 prior to and during the soldering and sintering step. The press 20 consists of an open configuration with a size being as big as overlapping the entire assembled structure just about to be subjected to pressure. The lower die 22 of the pressing apparatus 20 comprises a heating element 19 in order to be able to supply heat energy to the stack 10 of assembled component parts to be sintered and soldered simultaneously. The lower die 22 receives the base plate 3 with the DCB substrate to be soldered on the base plate and with the semiconductor chip 1 placed on top of the DCB substrate with a sintering paste 5 there between. The upper die 21 of the pressing apparatus 20 consists of an external boundary element 21a and an internal boundary element 21b which are displaceable against each other when pressure is applied onto the stack 10 that means when the upper die 21 is displaced onto the lower die 22. Within the open structure of the upper die 21 there is a soft cushion-like element 23 which is gently enough not to impose any harm to the component parts of the stack 10 to be sintered and soldered and which to a certain extent represents when being compressed a hydrodynamic pressing means. Pressing is indicated by the arrows 9.

Heating of the component parts is carried out during the process. The pressure exerted by the soft cushion-like element 23 is a quasi-hydrostatic pressure on the assembled component parts during the soldering and sintering step. The soft cushion-like material may comprise silicone rubber or any other suitable material known in the field.

FIG. 4b) shows the pressing apparatus 20 in a closed configuration, that means in a configuration overlapping the entire stack, that means the entire module structure, during the soldering and the sintering step of the process. The soft cushion-like element 23 completely surrounds the assembled component parts, that means the stack 10, and subjects the stack 10 to a quasi-hydrostatic pressure over the complete area of the assembled component parts. This enables the sintering to take place under the influence of the heated element. And the heat also allows the solder in the solder preform to melt and to form the solder join between the DCB substrate 2 and the base plate 3. Once the sintering process has been accomplished, the pressing apparatus opened and the assembled structure is cooled down, the solder material solidifies and forms the join between the DCB substrate and the base plate 3.

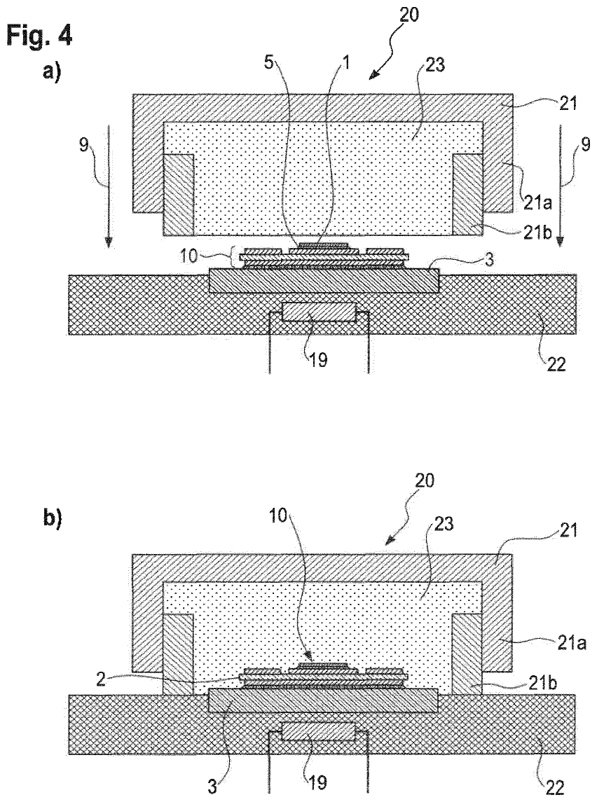

FIG. 5 shows an embodiment in a fully assembled form after soldering and sintering step have been successfully completed with the difference to FIG. 4b) in that the structure of the base plate has cooling channels 18 within it which are suitable for the passage of a fluid coolant for extracting heat generated by the semiconductor chip 1 when in use.

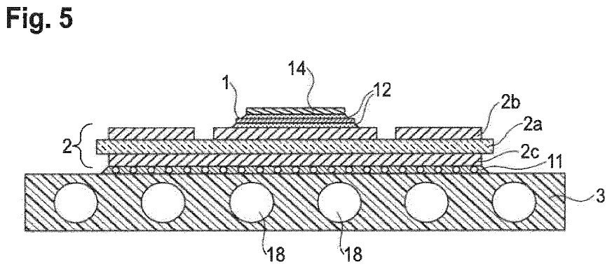

FIG. 6 shows another embodiment in a simplified form which illustrates just a substrate 2 and a base plate 3 with the substrate 2 having stabilizing means 7 in form of bumps 16 facing towards the upper side of the base plate.

FIG. 6a) shows the state just about before soldering without even the soldering layer between the two components.

FIG. 6b) illustrates the complete join where the solder lays between the substrate 2 and the base plate 3 as soldering layer 11. The bumps 16 ensure when the pressure is supplied for sintering and soldering process step that the space between the substrate 2 and the base plate 3 is just about as thick as the soldering layer 11 is supposed to be so that the high quality strength and other properties can be guaranteed.

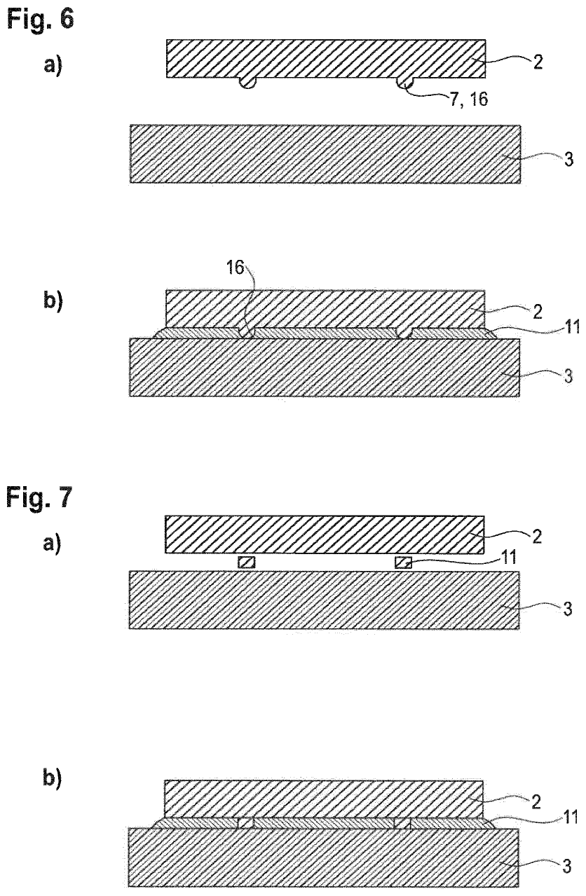

FIG. 7 shows a similar embodiment as the one of FIG. 6, however, instead of bumps arranged on the substrate 2 separate spacer elements as stabilizing means 7 are arranged within the soldering layer 11 between the substrate 2 and the base plate 3. The spacer elements ensure the sufficient distance between the substrate 2 and the base plate 3 when the soldering process step takes place to guarantee the required thickness of soldering layer 11 (see FIG. 7b)).

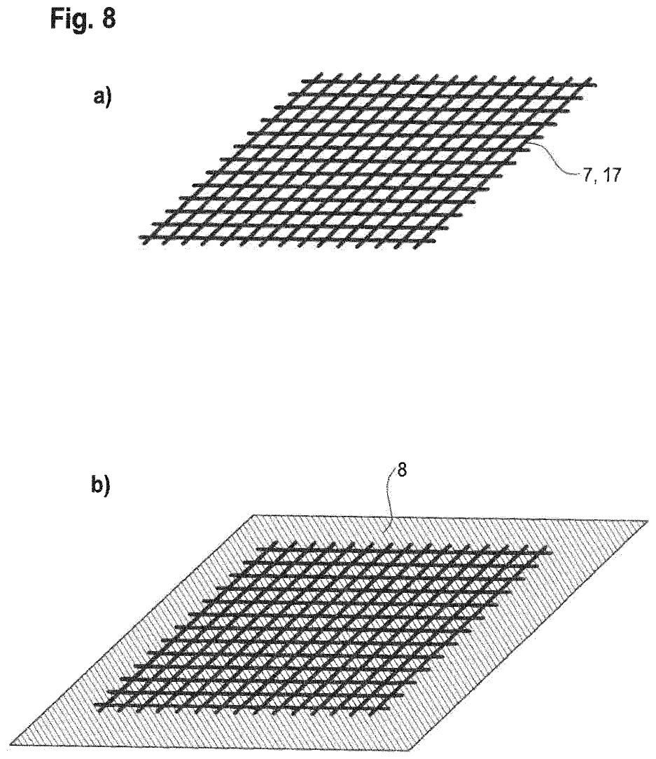

FIG. 8 shows an example of a solder preform 8 and how it is assembled.

FIG. 8a) illustrates a wire mesh, for example, made of copper wires. This metal wire mesh 17 represents the stabilizing means 7 to guarantee a proper spacing between the substrate 2 and the base plate (not shown) for ensuring the correct thickness of the soldering layer.

FIG. 8b) shows how this wire mesh is incorporated into a solder preform 8 which then can be inserted between the substrate and the base plate as described before.

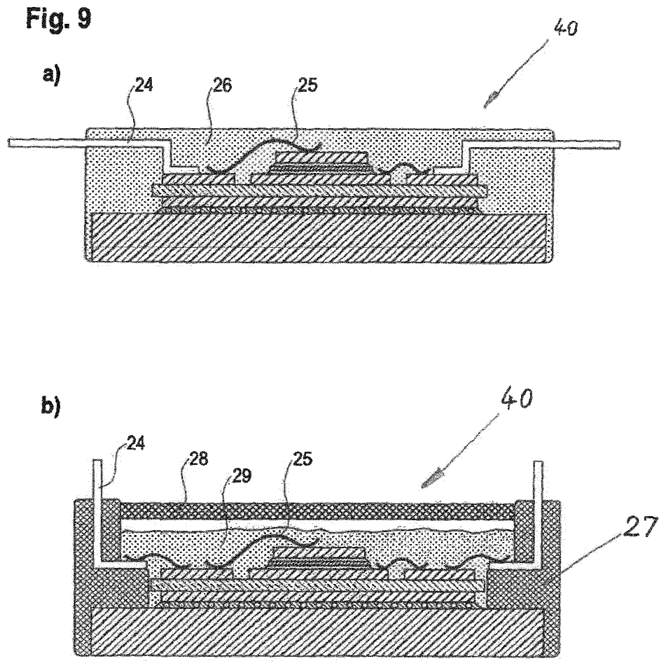

FIG. 9 shows two embodiments of a semiconductor power module with a semiconductor power module component according to FIG. 3.

The assembling of the power module 40 would be completed by the addition of connections 24 to the upper face of the DCB substrate and the various additional component parts thereon, using, as it is known in the prior art, wire bonds 25 or other mechanical connectors. Finally, this structure as represented in FIG. 3f) would be, for example, encapsulated using a mold compound (FIG. 9a)) or attached to a frame 27 but inbuilt connections (FIG. 9b)) to complete the power module, with a lid covering the power module component 30 together with the frame 27 and with a silicone protective filling 29.

FIG. 9a represents a molded semiconductor power module with the semiconductor power module component embedded in a molding compound, whereas FIG. 9b) represents a frame-based semiconductor power module with the semiconductor power module component embedded in a silicone gel protective filling.

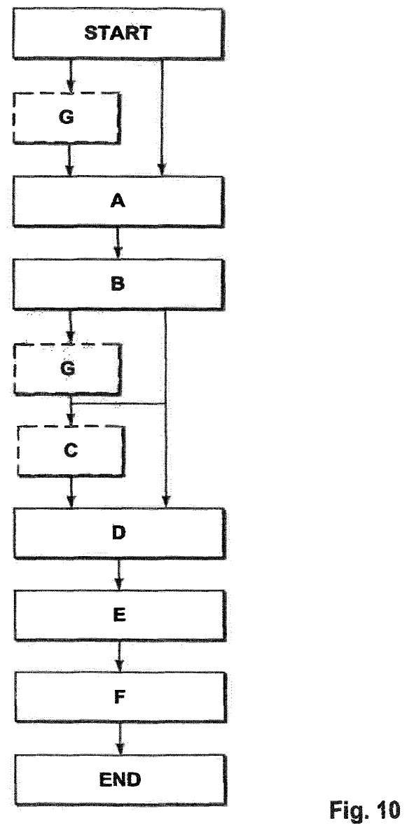

FIG. 10 shows a principal flow chart for the method of manufacturing an inventive semiconductor power module component.

The meanings of the various reference characters are:

START: Start

A: Applying sinter paste to a substrate or a chip which could be carried out by printing or by spraying or painting;

B: picking and placing the chip onto the sinter paste on the substrate;

C: preassembling of the substrate, if required, wherein preassembling comprises adding other components parts or other connections;

D: applying the preassembled substrate to a stack of base plate and solder with included stabilizing means in the form of spacers;

E: supplying heat energy to the stack to temperature of sintering and temperature of soldering, these temperatures being harmonized to each other;

F: feeding the stack of base plate and preassembled substrate into the sintering-soldering processing press and carrying out sintering and soldering at the respective temperature according to e).

G: For a module requiring a thermal buffer, such a stack with a thermal buffer can be placed by applying paste to the chip or the buffer and placing this kind of stack on the chip before carrying out step A or after step B.

END: End.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A method of assembling a semiconductor power module component comprising at least a first element, a second element and a third element arranged in a stack wherein the first element and the second element are joined by sintering in a sintering area and the second element and the third element are joined by soldering in a soldering area and wherein the sintering and the soldering are simultaneously executed, wherein the soldering area is heated to a temperature of soldering and the sintering area is heated to a temperature of sintering, the temperature of soldering and the temperature of sintering being harmonized to each other, and wherein pressure is applied to the stack comprising the soldering area and the sintering area with stabilizing means being arranged in the soldering area.

2. The method according to claim 1, wherein the pressure is applied to a complete area of the module component comprising at least the first element, the second element and the third element being component parts to be assembled together.

3. The method according to claim 1, wherein the stabilizing means are bumps on a surface of the second element facing the third element or on a surface of the third element facing the second element.

4. The method according to claim 1, wherein the stabilizing means remains solid during soldering.

5. The method according to claim 1, wherein the stabilizing means is solid spacer means placed between the second element and the third element.

6. The method according to claim 5, wherein the solid spacer means is incorporated with soldering material to form a solder preform.

7. The method according to claim 4, wherein the solder preform comprises substantially spherical bodies made of metal, in particular made of copper, glass or ceramics or comprises a wire mesh, in particular made of metal, in particular copper.

8. The method according to claim 1, wherein the second element is a DCB substrate and/or the third element is a base plate.

9. The method according to claim 1, wherein additional component parts are sintered onto the first element and/or the second element simultaneously with the sintering and the soldering of the stack.

10. A manufacturing system comprising a semiconductor power module component having at least a first element, a second element and a third element assembled as a stack, and a pressing apparatus having a heating and a pressing component, wherein the first element and the second element are joined by soldering in a soldering area of the stack and the second element and the third element are joined by sintering in a sintering area of the stack, wherein a heating component for heating to soldering temperature and to a sintering temperature is provided, the temperatures being harmonized to each other, and the pressing apparatus for applying pressure by a soft cushion-like element surrounding component parts of the module completely is provided, wherein soldering and sintering within the stack are carried out simultaneously.

11. The manufacturing system according to claim 10, wherein the soft cushion-like element is housed in an external and an internal boundary element which are displaceable against each other when pressed onto the stack to compress the soft cushion-like element.

12. The manufacturing system according to claim 10, wherein the semiconductor power module component comprises a stabilizing means within the soldering area for taking up the pressure exerted by the pressing apparatus and preventing solder material from being squeezed out of the soldering area.

13. A method of assembling a semiconductor power module comprising a semiconductor power module component assembled according to claim 1.

14. A method of assembling a semiconductor power module component for semiconductor power module with the following steps:
a) apply a sintering paste to a substrate or a chip by printing or by spraying or by painting;
b) pick and place the chip onto the sinter paste on the substrate;
c) apply the preassembled substrate to a stack of base plate and solder with included stabilizing means in the form of spacers;
d) supply heat energy to the stack to temperature of sintering and temperature of soldering, these temperatures being harmonized to each other;
e) feed the stack of base plate and preassembled substrate into the sintering-soldering processing press; and
f) carry out simultaneous sintering and soldering at the respective temperature and at the pressure applied by the process press.

15. The method according to claim 14, wherein preassembling comprises adding other component parts.

16. The method according to claim 14, wherein the steps a) to f) are carried out after the stack has been provided with a thermal buffer.

17. The method according to claim 14, in which step f) takes place in a process atmosphere comprising an inert gases such as nitrogen, process gases such as formic acid or a combination thereof.

18. The method according to claim 14, in which the step f) takes place at a pressure of 10 mbar to 1.5 bar.

19. A method of assembling a semiconductor power module comprising a semiconductor power module component as claimed in claim 1, and wherein connections are made to the upper face of the substrate, in particular DCB substrate, using wire bonds and in which the semiconductor power module component is encapsulated using a mold compound or attached to a frame with a lid and with a silicone protective filling.

20. The method according to claim 2, wherein the stabilizing means are bumps on a surface of the second element facing the third element or on a surface of the third element facing the second element.
